(19) United States
(12) Patent Application Publication
(10) Pub. No.: US 2011/0176023 A1
(43) Pub. Date: Jul. 21, 2011

(54) UNIT PICTURE ELEMENTS, BACK-SIDE ILLUMINATION CMOS IMAGE SENSORS INCLUDING THE UNIT PICTURE ELEMENTS AND METHODS OF MANUFACTURING THE UNIT PICTURE ELEMENTS

(76) Inventors: Tae-sub Jung, Anyang-si (KR); Bum-suk Kim, Hwaseong-si (KR); Jung-chak Ahn, Yongin-si (KR); Kyung-ho Lee, Suwon-si (KR)

(21) Appl. No.: 12/984,348

(22) Filed: Jan. 4, 2011

(30) Foreign Application Priority Data
Jan. 15, 2010 (KR) 10-2010-0003930

(51) Int. Cl. H04N 5/228; H01L 31/0232; H01L 27/146; H04N 5/335

(52) U.S. Cl. 348/222.1; 257/432; 257/294; 348/308; 257/E31.127; 257/E27.133; 348/E05.031; 348/E05.091

(57) ABSTRACT

Unit picture elements including photon-refracting microlenses. A unit picture element may include a photodiode, a metal layer, and a photo-refracting microlens. The photon-refracting microlens may be disposed between the photodiode and the metal layer. The photon-refracting microlens may refract photons reflected by the metal layer to a center portion of the photo diode.

### CROSS-REFERENCE TO RELATED APPLICATIONS

This application claims priority under 35 U.S.C. §119 to Korean Patent Application No. 10-2010-0003930, filed on Jan. 15, 2010, in the Korean Intellectual Property Office (KIPO), the entire contents of which is incorporated herein by reference.

### BACKGROUND

1. Field

Example embodiments of the inventive concepts relate to unit picture elements, and more particularly, to unit picture elements including photon-refracting microlenses.

2. Description of the Related Art

CMOS image sensors may include a plurality of unit picture elements (e.g., pixels), and may convert image signals sensed by the respective unit pixels into electrical signals. The unit pixel may include a photodiode for sensing incident image signals and a plurality of Metal Oxide Semiconductor (MOS) transistors for converting the sensed image signals into electrical signals. Image signals (e.g., light) are received from the upper side of a chip where a photodiode and MOS transistors are formed. Because MOS transistors and a photodiode may be formed in a unit pixel, the area of the photodiode receiving light inevitably occupies only a portion of the unit pixel.

A back-side illumination CMOS image sensor receives light from the lower side of a chip rather than the upper side. After a photodiode and MOS transistors constituting an image sensor are formed, a lower portion of a chip may be ground to an optimal thickness to receive light. Thereafter, a color filter and a microlens are further formed on the ground portion of the chip.

### SUMMARY

Example embodiments of the inventive concepts provide unit pixels including photon-refracting microlenses in which incident photons that pass through a photodiode and are reflected back towards the photodiode by a conductive layer (e.g., a metal layer) may be refracted towards a center of the photodiode.

Example embodiments of the inventive concepts provide a backside illumination complementary metal oxide semiconductor (CMOS) image sensor including a pixel array including a plurality of unit pixels, the respective unit pixels including a photon-refracting microlens in which incident photons that pass through a photodiode, and are reflected by a conductive layer back towards the photodiode, may be refracted to the center portion of the photodiode.

Example embodiments of the inventive concepts provide a method for forming a unit pixel having a photon-refracting microlens, in which photons that are incident, pass through a photodiode, and are reflected by a metal layer to the photodiode are allowed to be refracted to the center portion of the photodiode.

According to example embodiments of the inventive concepts, there is provided a unit pixel including a photodiode, a metal layer and a photon-refracting microlens between the photodiode and the metal layer, the photon-refracting microlens refracting photons reflected by the metal layer to a center portion of the photo diode.

According to other example embodiments of the inventive concepts, there is provided a unit pixel including a photon-refracting microlens on a photodiode over a substrate, a planarization layer over the photon-refracting microlens, and a metal layer over the planarization layer, the photon-refracting microlens having a convex portion toward the metal layer.

According to still other example embodiments of the inventive concepts, there is provided a backside illumination complementary metal oxide semiconductor (CMOS) image sensor including a pixel array including a plurality of unit pixels two dimensionally arranged therein, a row decoder horizontally controlling operation of the unit pixels arranged in the pixel array and a column decoder vertically controlling operation of the unit pixels arranged in the pixel array, the respective unit pixels including a photodiode, a metal layer, and a photon-refracting microlens between the photodiode and the metal layer, the photon-refracting microlens refracting photons reflected by the metal layer to a center portion of the photo diode.

According to further example embodiments of the inventive concepts, there is provided a method for forming a unit pixel having a photon-refracting microlens, the method including forming an island over a region defined as a photodiode and forming the photon-refracting microlens by annealing the island.

According to example embodiments of the inventive concepts, there is provided a unit pixel including a photodiode, a conductive layer and a photon-refracting microlens between the photodiode and the conductive layer, the photon-refracting microlens configured to refract photons reflected by the conductive layer towards a center region of the photo diode.

According to example embodiments of the inventive concepts, there is provided a unit pixel including a substrate, a photodiode on the substrate, a photon-refracting microlens on the photodiode, a planarization layer on a convex surface of the photon-refracting microlens, and a metal layer on the planarization layer.

According to example embodiments of the inventive concepts, there is provided a backside illumination complementary metal oxide semiconductor (CMOS) image sensor including a pixel array including a plurality of unit pixels, each unit pixel including a photodiode, a conductive layer, and a photon-refracting microlens, the photon-refracting microlens configured to refract light reflected by the conductive layer towards a center region of the photodiode, a row decoder and a column decoder.

Example embodiments of the inventive concepts provide a method for forming a unit pixel forming an island on a photodiode region and forming a photon-refracting microlens by annealing the island.

### BRIEF DESCRIPTION OF THE DRAWINGS

Example embodiments will be more clearly understood from the following brief description taken in conjunction with the accompanying drawings. FIGS. 1-14 represent non-limiting, example embodiments as described herein.

FIG. 1 is a schematic cross-sectional diagram illustrating unit pixels including photon-refracting microlenses according to example embodiments of the inventive concepts;

FIG. 2 is a schematic cross-sectional diagram illustrating a travelling direction of photons refracted by a photon-refracting microlens according to example embodiments of the inventive concepts;

FIG. 3 is a circuit diagram illustrating a unit pixel of a CMOS image sensor according to example embodiments of the inventive concepts;

FIG. 4 is a cross-sectional diagram illustrating a unit pixel generated by a CMOS process;

FIG. 5 is a cross-sectional diagram illustrating a unit pixel of a CMOS image sensor;

FIG. 6 is a schematic cross-sectional diagram illustrating a transfer path of photons in the absence of a photon-refracting microlens;

FIGS. 7-10 are cross-sectional diagrams illustrating methods of manufacturing a unit pixel of a CMOS image sensor according to example embodiments of the inventive concepts;

FIG. 11 is a graph illustrating sensitivity and cross talk of an experimental result according to example embodiments of the inventive concepts;

FIG. 12 is a circuit diagram illustrating a CMOS image sensor according to example embodiments of the inventive concepts;

FIG. 13 is a perspective view illustrating a camera including a photon-refracting microlens according to example embodiments of the inventive concepts; and

FIG. 14 is a block diagram illustrating a processor-based system including a backside illumination CMOS image sensor according to example embodiments of the inventive concepts.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments of the inventive concepts to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments of the inventive concepts. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Example embodiments of the inventive concepts may include a curved photon-refracting microlens between a conductive layer (e.g., a metal layer) and a photodiode. Photons with sufficient energy may pass through the photodiode and be reflected by the conductive layer. The reflected photons may be refracted by the microlens onto a center portion of the photodiode that the photons previously passed through. The reflected photons may not be reflected onto a neighbouring unit picture element (hereinafter referred to as pixel). One having ordinary skill in the art understands that although example embodiments are described with respect to photons, example embodiments are not bound to any particular theory of light and “photon” is used to denote a unit of light.

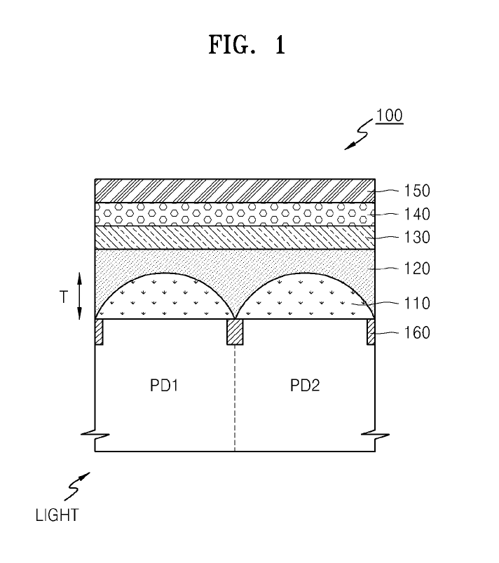

FIG. 1 is a schematic cross-sectional diagram illustrating unit pixels including photon-refracting microlenses according to example embodiments of the inventive concepts. Referring to FIG. 1, a multi-layer structure 100 illustrated in FIG. 1 may illustrate two of a plurality of unit pixels in a CMOS image sensor. At least one photon-refracting microlens 110 according to example embodiments may be on two photodiodes PD1 and PD2. A planarization layer 120, a first conductive layer 130, a dielectric layer 140, and a second conductive layer 150 may be on the photon-refracting microlens 110. The unit pixels PD1 and PD2 may be separated by a trench 160 filled with an insulating material.

A unit pixel of the multi-layer structure 100 may be used in a backside illumination CMOS image sensor according to example embodiments. Light LIGHT may be first received by surfaces of the photodiodes that are farthest from the first and second conductive layers 130 and 150. In contrast, light incident on a conventional CMOS image sensor may pass through two metal layers, an inter-metal dielectric layer, and a planarization layer, before entering a photodiode.

A photon-refracting microlens 110 may include a convex region adjacent to a first conductive layer 130. The thickness T of a thickest part of the convex region may be in a range from about 2,000 Å to about 3,500 Å (e.g., about 3,000 Å). When the thickness T of the thickest part of the convex region is less than about 3,500 Å, the effect according to example embodiments of inventive concept may be improved. The refractive index of a material of the photon-refracting microlens 110 may be greater than the refractive indices of materials of the planarization layer 120 and the dielectric layer 140. When the materials of the planarization layer 120 and the dielectric layer 140 are, for example, a silicon oxide, a silicon nitride may be used to form the photon-refracting microlens 110.

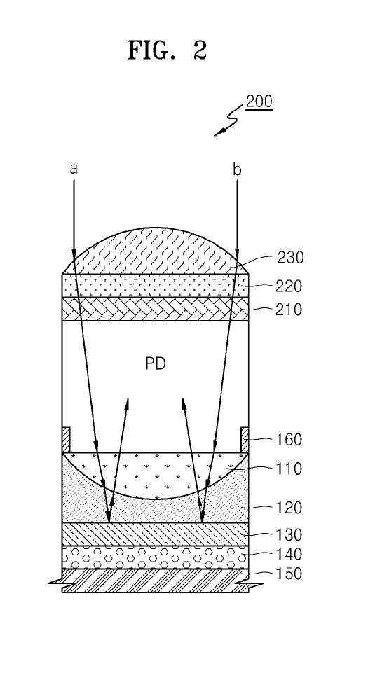

FIG. 2 is a schematic cross-sectional diagram illustrating a travelling direction of photons refracted by a photon-refracting microlens according to example embodiments of the inventive concepts. Referring to FIG. 2, a unit pixel 200 may be a unit pixel of a multi-layer structure 100 of FIG. 1. For example, the pixel 200 may be a pixel of the multi-layer structure 100 of FIG. 1 rotated 180 degrees (e.g., in an overturned state) and the lower portion of FIG. 1 may represent the upper portion of FIG. 2. According to example embodiments, the unit pixel 200 may include a color filter 210, a planarization layer 220 and a condensing microlens 230 on a side of a photodiode PD opposite the photon-refracting microlens 110. Light may be received at a backside surface of a substrate through, for example, the condensing microlens 230. The flat surface of the photo diode PD illustrated in FIG. 2 adjacent to the color filter 210 may be, for example, a backside of the substrate ground to a desired thickness. A CMOS image sensor including a unit pixel 200 may be called a backside illumination CMOS image sensor.

A photon “a” incident to a left edge of a unit pixel and a photon “b” incident to a right edge of the unit pixel may be refracted inwardly by the condensing microlens 230. The photons “a” and “b” may pass through the planarization layer 220, the color filter 210, and the photodiode PD. Most photons of incident light may generate electron-hole pairs in a photodiode region. Some of the incident photons, for example the two photons of FIG. 2, may pass through the photodiode of the photodiode PD. When photons pass through the photodiode, they may be reflected by a reflective layer on a side of the photodiode opposite a surface of the photodiode receiving incident light. For example, photons may be reflected by the first conductive layer 130. The reflected photons may travel into a neighbouring unit pixel to generate electron-hole pairs. Generation of electron-hole pairs in photodiodes other than the photodiode onto which photons are initially incident may be called cross-talk. A photon-refracting microlens according to example embodiments of the inventive concepts may refract the photons reflected by the first conductive layer 130 so that they travel towards the center of the photodiode PD. Cross-talk may be reduced according to example embodiments.

A photon “a” incident to the left edge of the unit pixel may pass through the photodiode PD and then may be refracted by the photon-refracting microlens 110. The refracted photon “a” may be reflected by the first conductive layer 130. Because the surface of the first conductive layer 130 may not be uniform, the travelling direction of the photon “a” reflected by the first conductive layer 130 may not be uniform. Although shown as if the photon is reflected to the center region of the photon-refracting microlens 110, the photon may be reflected in any radial direction. However, regardless of the direction of reflection, the photon “a” having reached the photon-refracting microlens 110 may be refracted towards a center region of the photodiode PD due to the curved surface of the photon-refracting microlens 110. If a material of the photon-refracting microlens 110 is of a higher refractive index than that of a material of the planarization layer 120, the angle of refraction of the photon “a” to the center region of the photodiode PD may be more acute. Because the photon “b” incident to the right edge of the unit pixel may be described in a similar way to the photon “a”, a detailed description thereof will be omitted herein.

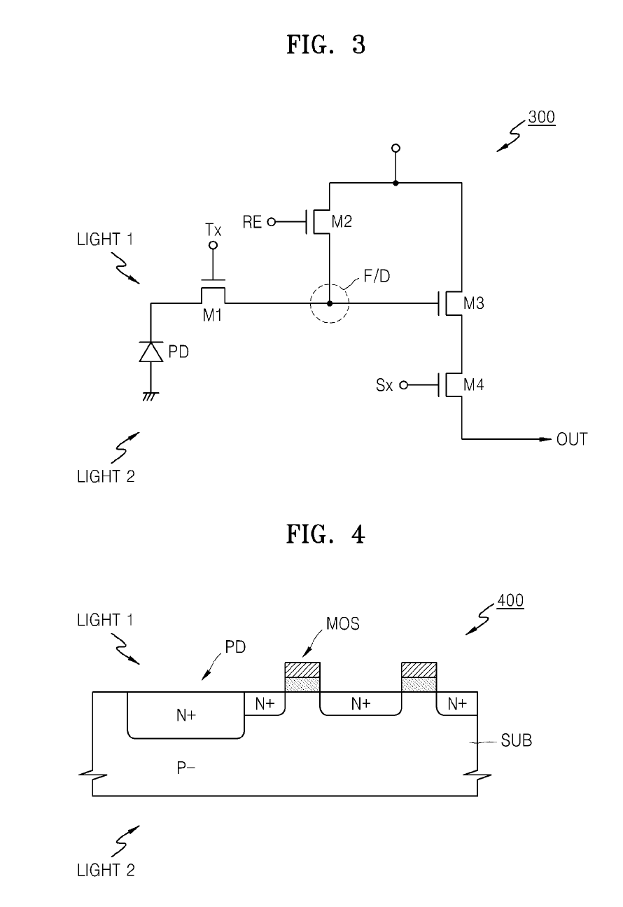

FIG. 3 is a circuit diagram illustrating a unit pixel of a CMOS image sensor according to example embodiments of the inventive concepts. Referring to FIG. 3, a unit pixel 300 may include a photodiode PD configured to sense photons, a transfer transistor M1 configured to transfer electric charges generated by the photons condensed by the photodiode PD to a floating diffusion region F/D, a reset transistor M2 configured to reset the floating diffusion region F/D, a conversion transistor M3 configured to generate electric signals corresponding to the electric charges delivered to the floating diffusion region F/D, and a select transistor M4 configured to deliver electrical signals converted in the unit pixel to an output terminal OUT.

The transfer transistor M1, the reset transistor M2 and the select transistor M4 may be controlled by a transfer control signal Tx, a reset control signal RE and a select control signal Sx. A conventional CMOS image sensor and a backside illumination CMOS image sensor may be differentiated by a direction in which light is received. The conventional CMOS image sensor may receive light LIGHT 1 incident to an N-type electrode of the photodiode PD. The backside illumination CMOS image sensor may receive light LIGHT 2 incident to a p-type electrode of the photodiode PD. In the conventional CMOS image sensor, a MOS transistor may inhibit a portion of the light LIGHT 1 incident to the unit pixel from reaching the photodiode. In a backside illumination CMOS image sensor, because the entirety of the unit pixel receives the light LIGHT 2, the efficiency of receiving light may be improved over a conventional CMOS image sensor.

FIG. 4 is a cross-sectional diagram illustrating a unit pixel generated by a CMOS process. Referring to FIG. 4, a unit pixel 400 formed using a CMOS process may include a photodiode PD and a MOS transistor MOS on a P− type substrate SUB. The photodiode PD may include two electrodes. One electrode may be the substrate SUB, and the other electrode may be an N+ type diffusion region. The MOS transistor MOS may include one N+ diffusion region forming part of the photodiode PD and a gate formed between two N+ diffusion regions. The MOS transistor MOS may be operated by a signal applied to the gate. The gate may be implemented using, for example, silicon oxide on the substrate and poly-silicon on the silicon oxide (e.g., SiO2). In order to control a threshold voltage of MOS the transistor MOS, the silicon oxide may be, for example, grown by a thermal growth (e.g., thermal oxidation).

An area receiving light LIGHT 2 when light LIGHT 2 is incident to the P-substrate SUB of the photodiode PD may be greater than an area receiving light LIGHT 1 when the light LIGHT 1 is applied to the N+ diffusion region of the photodiode PD. According to example embodiments of the inventive concepts, light LIGHT 2 may be incident to a P− substrate SUB of a photodiode PD of a backside illumination CMOS image sensor.

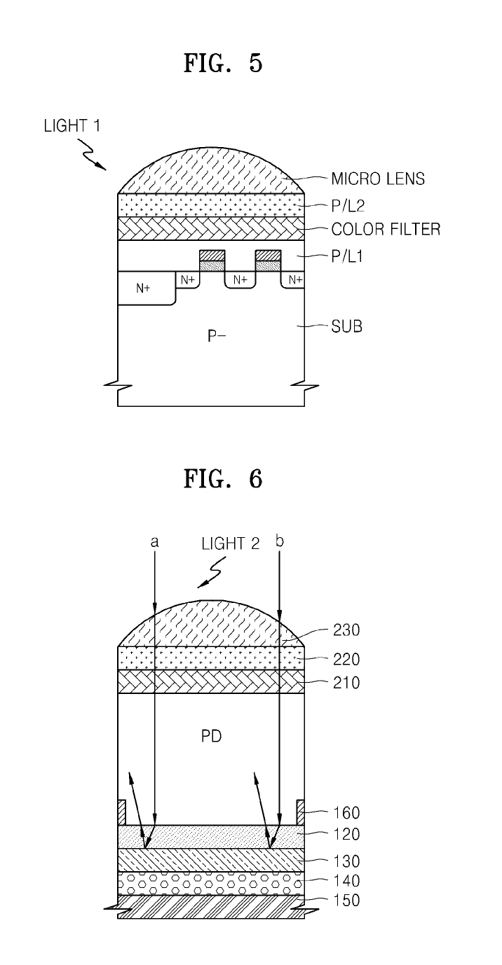

FIG. 5 is a cross-sectional diagram illustrating a unit pixel of a CMOS image sensor. Referring to FIG. 5, a unit pixel of a CMOS image sensor may include a photodiode and transistors on a P− substrate SUB, a first planarization layer P/L1, a color filter COLOR FILTER, a second planarization layer P/L2, and a condensing microlens MICRO LENS. Although not specifically shown in FIG. 5, at least one interlayer dielectric and at least one conductive layer (e.g., a metal layer) may be further disposed under the first planarization layer P/L1.

In a unit pixel of the CMOS image sensor shown in FIG. 5, light LIGHT 1 may be commonly incident to a region where a limited photodiode region and transistors are located. The photodiode may be implemented using a substrate P− as one electrode and a leftmost N+ type diffusion region N+ as the other electrode. When light LIGHT 1 is incident to the N+ type diffusion region N+ forming the other electrode, the photodiode may sense the light LIGHT 1. When light LIGHT 1 is incident to the transistors, the light LIGHT 1 may not reach the P− substrate SUB forming one electrode of the photodiode due to various interlayer materials forming the transistors. A reduction of sensing efficiency may result. Although photodiodes are described with reference to doping conventions, example embodiments are not limited to the doping schemes described.

FIG. 6 is a schematic cross-sectional diagram illustrating a transfer path of photons in the absence of a photon-refracting microlens. In a CMOS image sensor illustrated in FIG. 6, light LIGHT 2 may be incident onto a P− substrate forming one electrode of a photodiode PD. The CMOS image sensor of FIG. 6 may have a structure capable of receiving more light than the CMOS image sensor of FIG. 5. Referring to FIG. 6, photons “a” and “b” that have passed through a condensing microlens 230, a planarization layer 220, and a color filter 210 may pass through a photodiode PD and a planarization layer 120. Photons “a” and “b” may be reflected by a first conductive layer 130. The reflection direction of the photons “a” and “b” may not be uniform. If the photons “a” and “b” are not reflected to their corresponding photodiode but cross to a photodiode of a neighbouring pixel, cross-talk may occur.

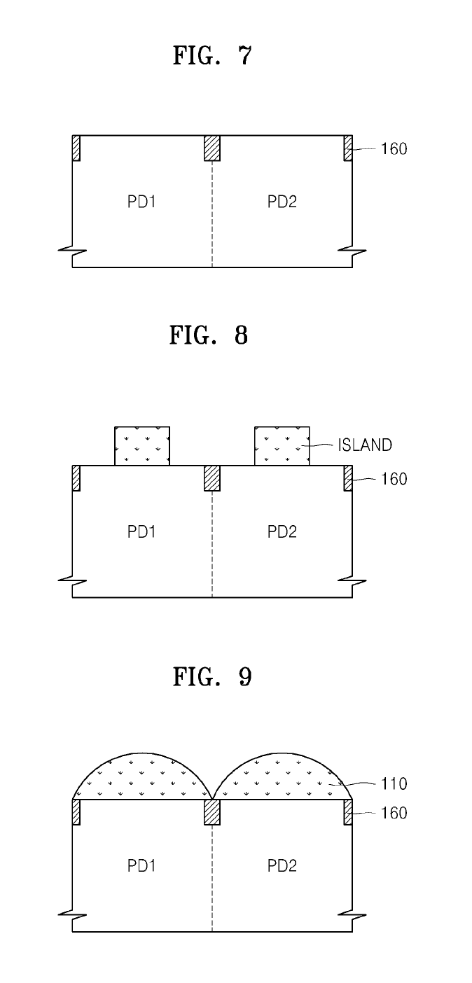

FIGS. 7-10 are cross-sectional diagrams illustrating methods of manufacturing a unit pixel of a photodiode according to example embodiments of the inventive concepts. Referring to FIG. 7, two photodiodes PD1 and PD2 may be divided by a trench structure 160 filled with an insulating material. Referring to FIG. 8, islands may be formed on the photodiodes PD1 and PD2. The islands may have a smaller size than regions defined by the photodiodes PD1 and PD2. One island ISLAND may be formed in each unit pixel. The size of the island ISLAND may be varied with a subsequent process. The island ISLAND may be of a shape that is scaled down from a shape of the photodiode PD2. For example, if the shape of the photodiode PD2 is rectangular, the shape of the island ISLAND may also be rectangular. If the shape of photodiode PD2 is hexagonal and/or octagonal, the shape of the island ISLAND may also be hexagonal and/or octagonal. The shape of the island ISLAND is not limited. For example, the shape of the island ISLAND may be circular according to example embodiments.

According to example embodiments, a material for forming a photon-refracting microlens 110 may be deposited on the photodiode PD2 (not shown). A mask defining the island ISLAND may be formed (not shown). The island ISLAND may be defined in photoresist using the mask (not shown). A portion of the photo-resist other than the portion defined as the island ISLAND may be removed. The island ISLAND may be formed by removing the material for Banning the photon-refracting microlens 110 not covered by the photoresist (not shown). For example, the material for forming the photon-refracting microlens 110 may be removed using an etchant.

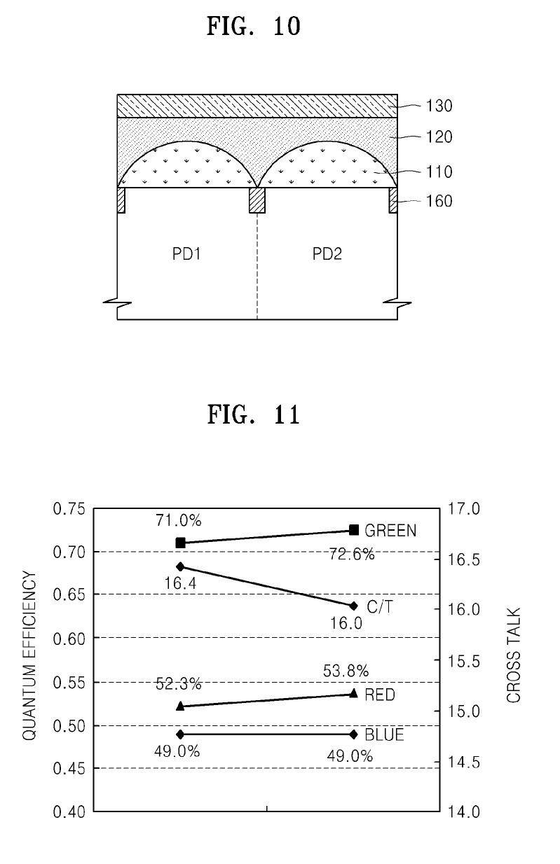

Referring to FIG. 9, a typical annealing process may be performed to form the photon-refracting microlens 110. The annealing process may flow the island ISLAND into a convex shape of a photon-refracting microlens 110. Referring to FIG. 10, a planarization layer 120 and a first conductive layer 130 (e.g., a metal layer) may be formed on the photon-refracting microlens 110. The planarization layer 120 and the first conductive layer 130 shown in FIG. 10 may be formed by a typical process used to implement elements such as transistors of a unit pixel. If the same material as a material used for the photon-refracting microlens 110 is used in a typical process, and an additional process for forming an island is unnecessary, then the photon-refracting microlens may be formed by a process for forming only a mask defining the island.

FIG. 11 is a graph illustrating sensitivity and cross talk of an experimental result according to example embodiments of the inventive concepts. In FIG. 11, values of cross talk C/T and sensitivity with respect to three colors (Red, Green, and Blue) in the absence of a photon-refracting microlens may be compared to those in the presence of the photon-refracting microlens. The sensitivity with respect to the three colors (Red, Green, and Blue) may be illustrated with respect to values defined as quantum efficiency. The quantum efficiency may be defined as a number of electron-hole pairs generated by one photon.

Referring to FIG. 11, light passed through a green color filter may achieve a quantum efficiency of about 71% in the absence of a photon-refracting microlens 110 and an increased quantum efficiency of about 72.6% in the presence of a photo-refracting microlens 110. Quantum efficiency of light passed through a red color filter may increase from about 52.3% to about 53.8% in the presence of a photo-refracting microlens 110. Quantum efficiency of light passed through a blue color filter may be the same despite the presence of a photo-refracting microlens 110. According to example embodiments, quantum efficiency of light passed through green and red color filters and the photon-refracting microlens 110 may be increased over light passed through green and red color filters and no photon-refracting microlens 110. A value of cross-talk C/T may be reduced from about 16.4 to about 16 in the presence of a photo-refracting microlens. The value of cross talk C/T may be a value that is normalized using a reference value.

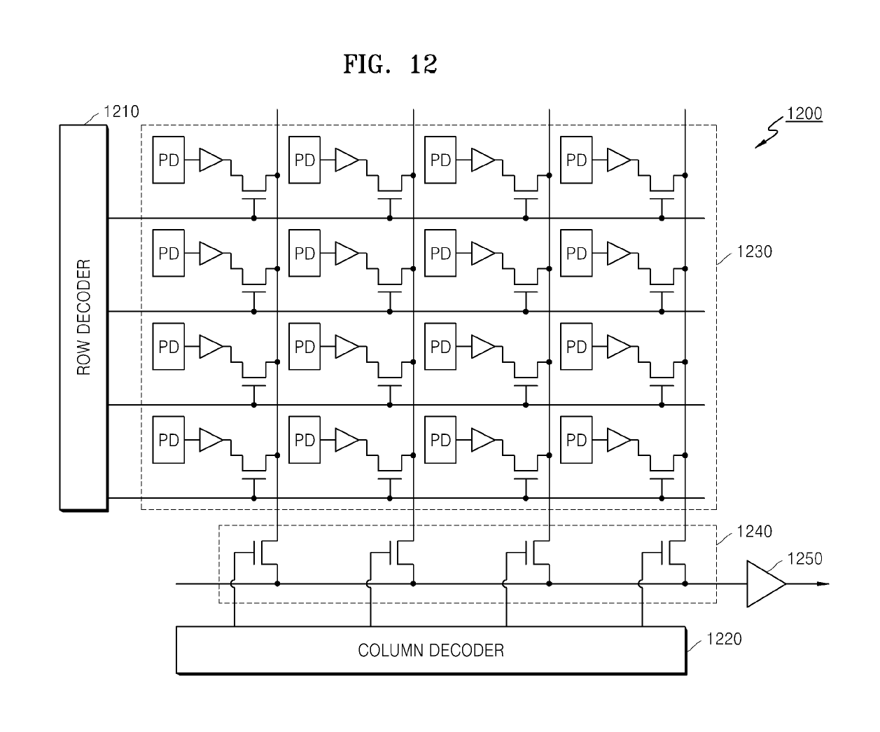

FIG. 12 is a circuit diagram illustrating a configuration of a CMOS sensor according to example embodiments of the inventive concepts. Referring to FIG. 12, a CMOS image sensor 1200 may include a row decoder 1210, a column decoder 1220, a pixel array 1230, a selector 1240 and a buffer 1250. The pixel array 1230 may include a plurality of unit pixels including photo diodes PD two-dimensionally arranged therein. The row decoder 1210 may control the operations of the unit pixels arranged in the pixel array 1230 by unit of horizontal line. The column decoder 1220 may control the selector 1240 to control the operations of the unit pixels arranged in the pixel array 1230 by unit of vertical lines. Electrical signals converted from the pixel array 1230 may be output through the buffer 1250. According to example embodiments, the unit pixel constituting the pixel array 1230 may include a structure similar to that illustrated in FIG. 1.

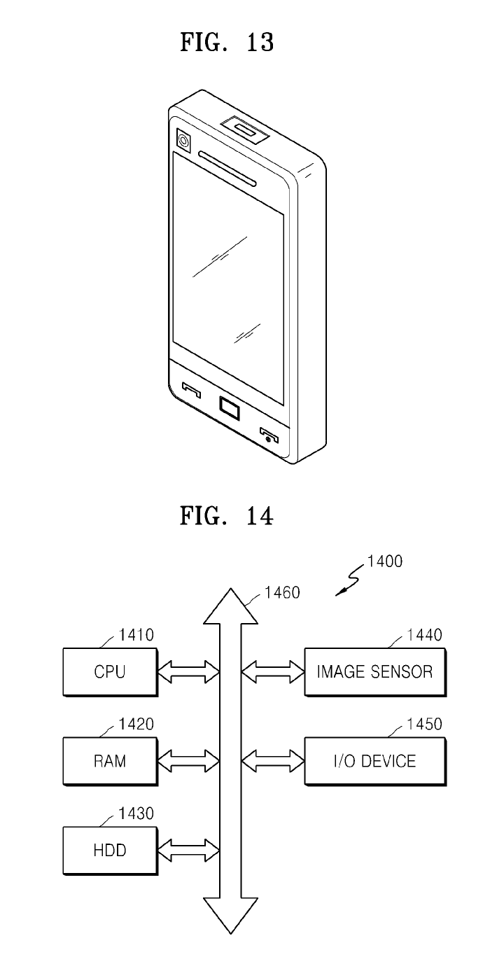

FIG. 13 is a perspective view illustrating a small-sized camera including a photon-refracting microlens according to example embodiments of the inventive concepts. According to example embodiments, the camera of FIG. 13 may include a CMOS image sensor including a photon-refracting microlens.

FIG. 14 is a block diagram schematically illustrating a processor-based system 1000 that includes a backside illumination CMOS image sensor 1440. Referring to FIG. 14, the processor-based system 1400 may include a processor (CPU) 1410, a random access memory (RAM) 1420, a hard drive (HDD) 1430, a backside illumination CMOS image sensor 1440 and an input/output (I/O) device 1450 which may communicate with one another via a bus 1460. The backside illumination CMOS image sensor 1440 may be one of the image sensors described above with reference to FIGS. 1-13. The backside illumination CMOS image sensor 1440 may receive a control signal and/or data from the processor 1410 and/or the other elements of the processor-based system 1400. The backside illumination CMOS image sensor 1440 may supply a signal that defines an image based on the control signal and/or the data to the processor 1410. The processor 1410 may process the signal received from the backside illumination CMOS image sensor 1440.

Examples of the processor-based system 1400 may include, for example, a digital circuit, a computer system, a camera system, a scanner, a video telephone, an electronic surveillance system, a vehicle navigation system, an automatic focus system, a star tracker system, a movement detection system, an image stabilization system, a data compression system, and/or other various systems that may include a backside illumination CMOS image sensor according to example embodiments.

While example embodiments of the inventive concepts have been particularly shown and described, it will be understood by one of ordinary skill in the art that variations in faun and detail may be made therein without departing from the spirit and scope of the claims.

1. A unit picture element (pixel), comprising:
a photodiode;
a conductive layer; and
a photon-refracting microlens between the photodiode and the conductive layer, the photon-refracting microlens configured to refract photons reflected by the conductive layer towards a center region of the photo diode.

2. The unit pixel of claim 1, wherein at least one surface of the photon-refracting microlens is convex in a direction of the conductive layer.

3. The unit pixel of claim 2, wherein a maximum thickness of the photon-refracting microlens is about 2,000 angstroms to about 3,500 angstroms.

4. The unit pixel of claim 2, further comprising:
at least one planarization layer between the photon-refracting microlens and the conductive layer.

5. The unit pixel of claim 4, wherein a refractive index of the photon-refracting microlens is greater than a refractive index of the at least one planarization layer.

6. The unit pixel of claim 5, wherein the at least one planarization layer includes a silicon oxide, and
the photon-refracting microlens includes a silicon nitride.

7. A unit picture element (pixel), comprising:
a substrate;
a photodiode on the substrate;
a photon-refracting microlens on the photodiode;
a planarization layer on a convex surface of the photon-refracting microlens; and
a metal layer on the planarization layer.

8. The unit pixel of claim 7, wherein a maximum thickness of the photon-refracting microlens is about 2,000 angstroms to about 3,500 angstroms.

9. The unit pixel of claim 8, wherein a refractive index of the photon-refracting microlens is greater than a refractive index of the planarization layer.

10. The unit pixel of claim 9, wherein the planarization layer includes a silicon oxide, and
the photon-refracting microlens includes a silicon nitride.

11. A backside illumination complementary metal oxide semiconductor (CMOS) image sensor, comprising:
a pixel array including a plurality of unit pixels, each unit pixel including a photodiode, a conductive layer, and a photon-refracting microlens, the photon-refracting microlens configured to refract light reflected by the conductive layer towards a center region of the photodiode;
a row decoder; and
a column decoder.

12. The backside illumination CMOS image sensor of claim 11, wherein the photon-refracting microlens is at least partially convex in a direction of the conductive layer.

13. The backside illumination CMOS image sensor of claim 12, wherein a maximum thickness of the photon-refracting microlens is about 2,000 angstroms to about 3,500 angstroms.

14. The backside illumination CMOS image sensor of claim 12, wherein at least one of the plurality of unit pixels further includes at least one planarization layer between the photon-refracting microlens and the conductive layer.

15. The backside illumination CMOS image sensor of claim 14, wherein a refractive index of the photon-refracting microlens is greater than a refractive index of the at least one planarization layer.

16. The backside illumination CMOS image sensor of claim 15, wherein the planarization layer includes a silicon oxide, and
the photon-refracting microlens includes a silicon nitride.

17-20. (canceled)

21. A camera, comprising the backside illumination CMOS image sensor of claim 11.

22. A processor based system, comprising:
a processor;
a random access memory;
a hard drive;
the backside illumination CMOS image sensor of claim 11; and
an input/output device.
